(19) United States
(12) Patent Application Publication
(10) Pub. No.: US 2026/0367112 A1
(43) Pub. Date: Nov. 19, 2026

(54) HIGH-FREQUENCY PROBE UNIT AND INSPECTION DEVICE

(71) Applicant: KABUSHIKI KAISHA NIHON MICRONICS, Tokyo (JP)

(72) Inventors: Takashi OGASAWARA, Musashino-shi (JP); Tomokazu SAITO, Musashino-shi (JP); Megumi AKAHIRA, Musashino-shi (JP); Harutada DEWA, Musashino-shi (JP)

(73) Assignee: KABUSHIKI KAISHA NIHON MICRONICS, Tokyo (JP)

(21) Appl. No.: 19/645,898

(22) Filed: Apr. 13, 2026

(30) Foreign Application Priority Data
May 16, 2025 (JP) 2025-082679
Sep. 8, 2025 (JP) 2025-148404

(51) Int. Cl. G01R 1/067

(52) U.S. Cl. CPC G01R 1/06772; G01R 1/06722

(57) ABSTRACT

A high-frequency probe unit includes a probe which comes into contact with an inspection target, and a main body portion which supports the probe and to which a high-frequency cable for transmitting and receiving a high-frequency signal to and from the inspection target via the probe is attachable, in which the probe includes a fixed end portion fixed to the main body portion, a pair of elastic arm portions branching from the fixed end portion and extending with a gap therebetween, a free end portion connecting distal ends of the pair of elastic arm portions, and a pin portion provided on the free end portion and coming into contact with the inspection target.

### BACKGROUND OF THE INVENTION

### Field of the Invention

The present invention relates to a high-frequency probe unit and an inspection device.

Priority is claimed on Japanese Patent Application No. 2025-082679 filed on May 16, 2025, and Japanese Patent Application No. 2025-148404 filed on Sep. 8, 2025, the contents of which are incorporated herein by reference.

### Description of Related Art

Conventionally, in order to inspect electrical characteristics of a high-frequency device such as a semiconductor integrated circuit, a high-frequency probe device that directly comes into contact with electrodes, signal lines, and the like of a high-frequency device, which is an inspection target, is known (see Japanese Unexamined Patent Application, First Publication No. 2006-194765).

This high-frequency probe device includes a probe formed of a thin plate-shaped composite material including a base metal and an insulating layer formed on the base metal, and having a contact point and a signal line of a microstrip line structure formed on the insulating layer, and an attachment unit to which the probe is detachably attached.

### SUMMARY OF THE INVENTION

Incidentally, during overdrive (hereinafter may be referred to as “OD”) when a high-frequency probe device is brought into contact with an inspection target, it is necessary to bring a probe of the high-frequency probe device into contact with a pad of the inspection target. The probe of the above-described Patent Document 1 has slits that divide a distal end portion thereof into a plurality of portions to provide a contact point with the pad on each of the portions. Therefore, although the portions divided by the slits are easily elastically deformable individually, they are also easily deformed by a reaction force received from the pad during OD, and thus there is still room for improvement in stably bringing the contact point of the probe into contact with the pad.

The present invention has been made in view of the above-described problems, and an objective thereof is to provide a high-frequency probe unit and an inspection device capable of stably bringing a probe into contact with an inspection target and appropriately inspecting electrical characteristics of the inspection target via a high-frequency signal.

A high-frequency probe unit according to one aspect of the present invention includes a probe which comes into contact with an inspection target, and a main body portion which supports the probe and to which a high-frequency cable for transmitting and receiving a high-frequency signal to and from the inspection target via the probe is attachable, in which the probe includes a fixed end portion fixed to the main body portion, a pair of elastic arm portions branching from the fixed end portion and extending with a gap therebetween, a free end portion connecting distal ends of the pair of elastic arm portions, and a pin portion provided on the free end portion and coming into contact with the inspection target.

Also, an inspection device according to one aspect of the present invention is connected to the main body portion of the high-frequency probe unit described above via the high-frequency cable and inspects electrical characteristics of the inspection target.

According to above-described one aspect of the present invention, a probe can be stably brought into contact with an inspection target, and electrical characteristics of the inspection target can be appropriately inspected via a high-frequency signal.

### BRIEF DESCRIPTION OF THE DRAWINGS

FIG. 1 is an overall configuration view of an inspection device according to a first embodiment.

FIG. 2 is a perspective view of a high-frequency probe unit according to the first embodiment from above.

FIG. 3 is a perspective view of the high-frequency probe unit according to the first embodiment from below.

FIG. 4 is a plan view of a probe and a dummy probe according to the first embodiment.

FIG. 5 is an explanatory view illustrating a state in which the probe is elastically deformed during OD of the high-frequency probe unit according to the first embodiment.

FIG. 6 is a plan view of a probe and a dummy probe according to a second embodiment.

FIG. 7 is a plan view of a probe and a dummy probe according to a third embodiment.

FIG. 8 is a perspective view of a probe and a dummy probe according to a fourth embodiment.

FIG. 9 is a plan view of the probe and the dummy probe according to the fourth embodiment.

FIG. 10 is a perspective view of a high-frequency probe unit according to a fifth embodiment from a front upper side.

FIG. 11 is a perspective view of the high-frequency probe unit according to the fifth embodiment from a rear upper side.

FIG. 12 is a side view of the high-frequency probe unit according to the fifth embodiment.

### DETAILED DESCRIPTION OF THE INVENTION

Hereinafter, an embodiment of the present invention will be described on the basis of the drawings. However, the embodiment described below is intended to exemplify apparatuses and methods for embodying the technical ideas of this invention, and the embodiment of the invention is not intended to limit materials, shapes, structures, arrangements, and the like of the components to those described below.

### First embodiment

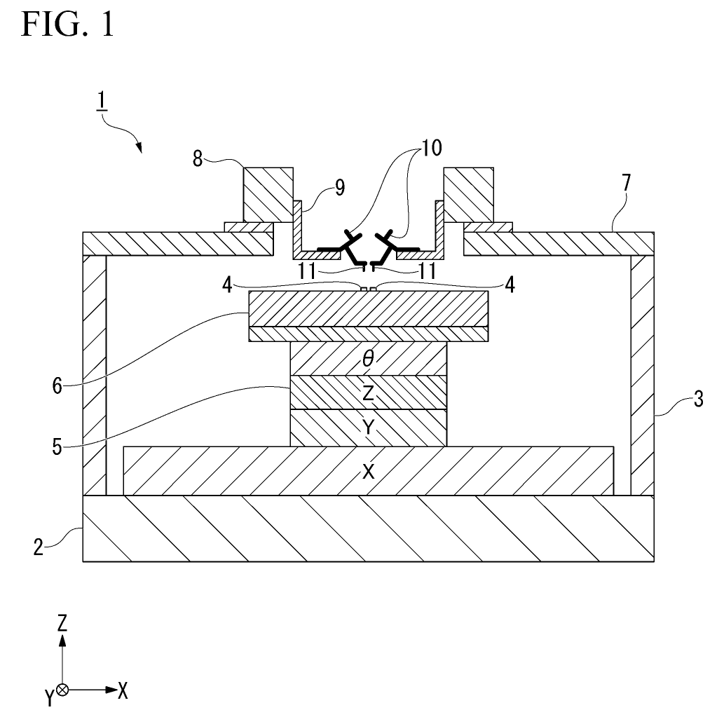

FIG. 1 is an overall configuration view of an inspection device 1 according to a first embodiment. Further, an X-axis direction, a Y-axis direction, and a Z-axis direction are defined in FIG. 1. In FIG. 1, the X-axis direction (first direction) is a left-right direction, the Y-axis direction (second direction) is a front-rear direction, and the Z-axis direction (third direction) is a vertical direction.

The inspection device 1 inspects electrical characteristics of an inspection target 4 such as a high-frequency device including a semiconductor integrated circuit. The inspection device 1 inspects electrical characteristics of the inspection target 4 by electrically bringing a probe 11 into contact with a pad (electrode terminal) of the inspection target 4. The inspection device 1 is also referred to as a prober.

As illustrated in FIG. 1, the inspection device 1 includes a base portion 2, a frame portion 3, a moving device 5, a mounting table 6, a top plate 7, a manipulator 8, a unit attachment portion 9, and a high-frequency probe unit 10.

Further, the inspection device 1 is not limited to the configuration illustrated in FIG. 1, and can also be applied to, for example, a prober that does not include the base portion 2 and the frame portion 3, or a prober that uses simple members instead of the base portion 2 and the frame portion 3. It may also include a microscope, a laser cutter device, and the like.

The mounting table 6 is configured to mount a high-frequency device, a semiconductor chip, a wafer, or the like as the inspection target 4. Further, the mounting table 6 may have a temperature adjustment function for adjusting a temperature of the inspection target 4 to a high temperature or a low temperature.

The moving device 5 moves the mounting table 6 on which the inspection target 4 is placed, and positions the pad of the inspection target 4 with respect to the probe 11. For example, the moving device 5 has an X-axis moving portion that moves the mounting table 6 in the X-axis direction, a Y-axis moving portion that moves the mounting table 6 in the Y-axis direction, a Z-axis moving portion that moves the mounting table 6 in the Z-axis direction, and a θ rotation portion that rotates the mounting table 6 in a θ direction around the Z axis. Further, the moving device 5 is not limited to the configuration described above as long as it can position the pad of the inspection target 4 with respect to the probe 11.

The high-frequency probe unit 10 includes the probe 11 that is brought into electrical contact with the pad of the inspection target 4 and is configured to transmit and receive a high-frequency signal to and from the inspection target 4 via the probe 11. FIG. 1 illustrates an example in which two high-frequency probe units 10 are provided.

The high-frequency probe unit 10 is attached to the unit attachment portion 9 of the manipulator 8 to be connected to a high-frequency cable (for example, a coaxial cable) (not illustrated) and is configured to align the probe 11 with the pad of the inspection target 4 by operating the manipulator 8.

The manipulator 8 is provided on the top plate 7 and is configured to align the high-frequency probe unit 10. The manipulator 8 may be manually operated by an operator or may be automatically controlled.

During inspection, the probe 11 of the high-frequency probe unit 10 is brought into contact with the pad of the inspection target 4. The inspection device 1 applies a high-frequency signal to the inspection target 4 via the probe 11 and acquires a response signal from the inspection target 4 via the probe 11. In this way, electrical characteristics of the high-frequency device are inspected. For example, the inspection device 1 inspects electrical characteristics of the high-frequency device using a high-frequency signal (for example, a signal in a 20 GHz band) from a coaxial cable. Further, the inspection device 1 may inspect electrical characteristics of the high-frequency device using a signal in a DC (0 Hz) to 46.5 GHz band.

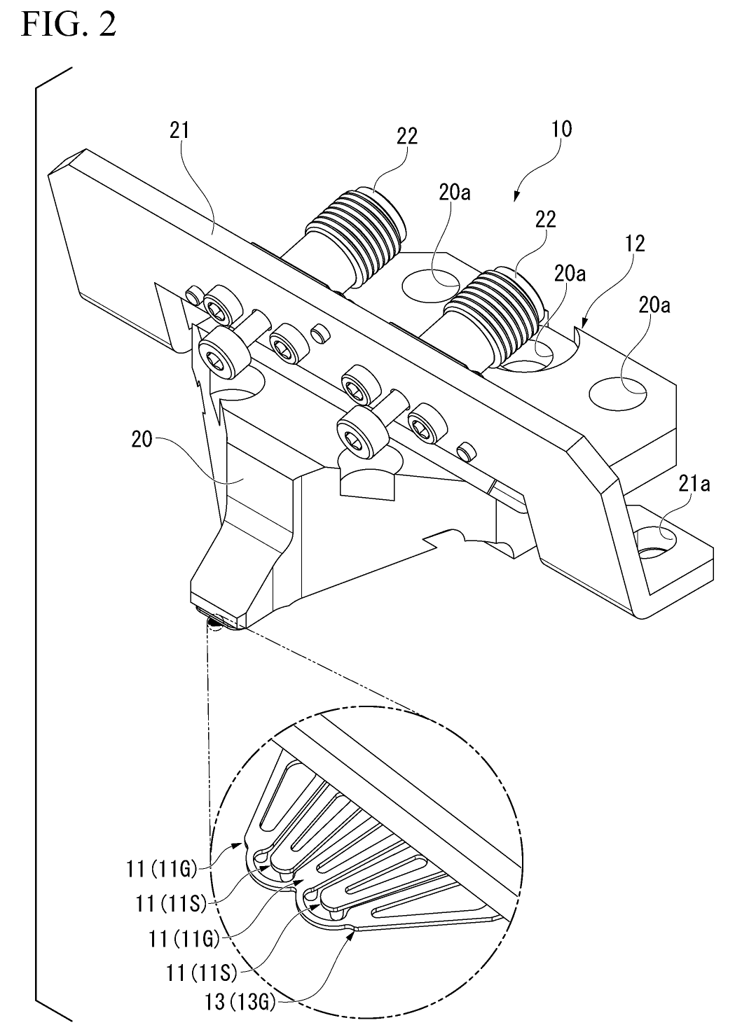

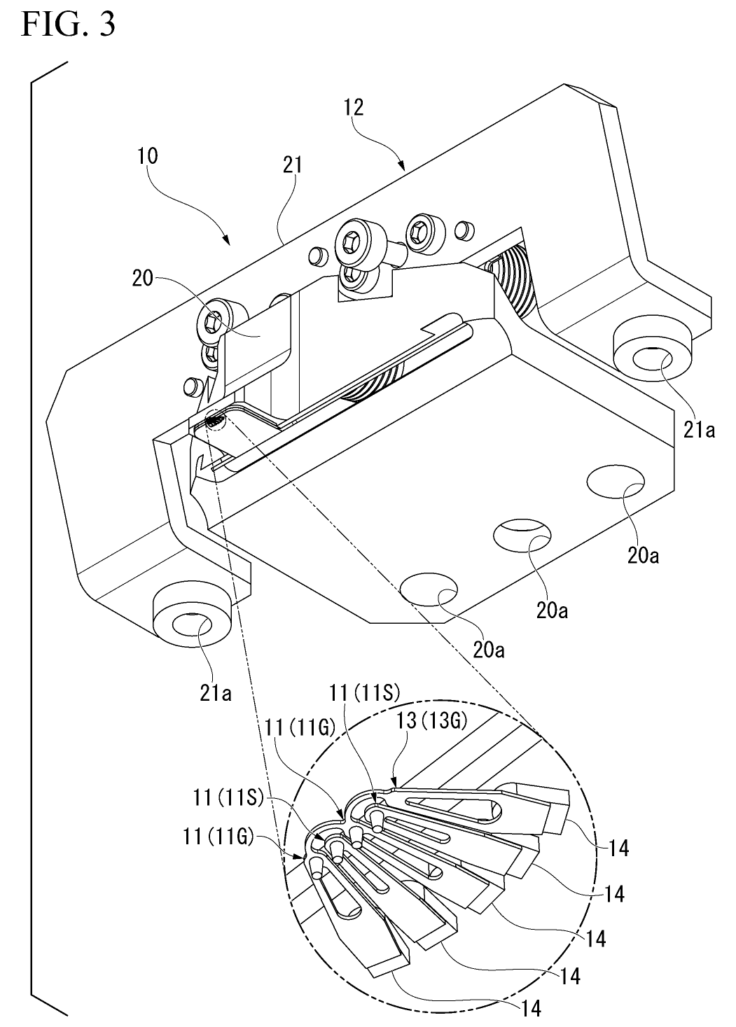

FIG. 2 is a perspective view of the high-frequency probe unit 10 according to the first embodiment from above. FIG. 3 is a perspective view of the high-frequency probe unit 10 according to the first embodiment from below. Further, FIGS. 2 and 3 include enlarged views of a vicinity of the probe 11 of the high-frequency probe unit 10.

As illustrated in these figures, the high-frequency probe unit 10 includes the probe 11 that comes into contact with the inspection target 4 and a main body portion 12 that supports the probe 11.

The main body portion 12 includes a probe block 20 supporting the probe 11, and a connector holder 21 having a connector 22 to which a high-frequency cable can be attached. The probe block 20 is a main member of the high-frequency probe unit 10, and supports the probe 11 and a dummy probe 13 to be described later on a lower surface side of a distal end part protruding in a horizontal direction. The probe block 20 includes a wiring board (not illustrated) that is electrically connected to the probe 11 and the dummy probe 13.

The probe block 20 has three attachment holes 20a formed at a base end part thereof. The base end part of the probe block 20 is attached to the unit attachment portion 9 via fixing members (screws or the like) inserted through the three attachment holes 20a. As illustrated in the enlarged view of FIG. 3, the probe 11 and the dummy probe 13 are cantilever-supported by the probe block 20 via a pedestal portion 14. Further, the probe 11 and the dummy probe 13 may be cantilever-supported directly by the probe block 20 without interposing the pedestal portion 14.

As illustrated in FIG. 2, the connector holder 21 is provided with a pair of connectors 22 (coaxial connectors) to which high-frequency cables (coaxial cables) (not illustrated) of the inspection device 1 can be attached. The connectors 22 are electrically connected to the wiring board of the probe block 20 via flexible printed circuits (FPCs) or the like (not illustrated). Thereby, the probe 11 and the connector 22 are electrically connected.

The connector holder 21 is formed in a gate shape or a saddle shape (an inverted U shape) that straddles an upper side of the probe block 20. Thereby, the connector holder 21 is configured to be elastically deformable independently of the probe block 20 that supports the probe 11. A pair of attachment holes 21a are formed in a pair of leg portions of the connector holder 21. The connector holder 21 is attached to the unit attachment portion 9 via fixing members (such as screws) inserted through the pair of attachment holes 21a. Further, the connector holder 21 is not limited to a configuration in which it is attached to the unit attachment portion 9, and may have a configuration in which it is attached to the main body portion 12. For example, the connector holder 21 may be attached to the base end part of the probe block 20 via a fixing member.

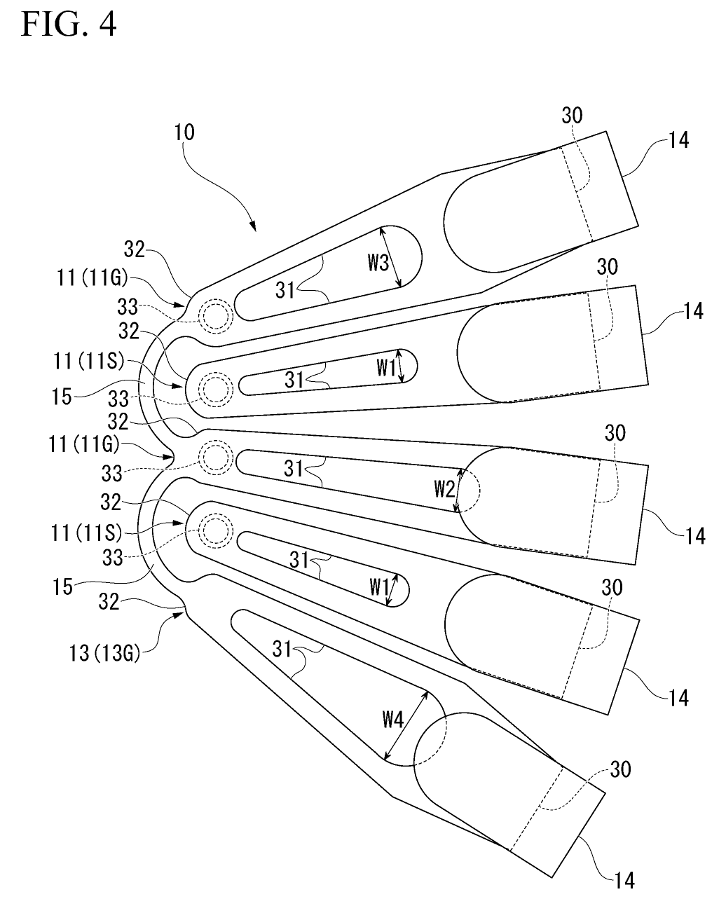

FIG. 4 is a plan view of the probe 11 and the dummy probe 13 according to the first embodiment. As used herein, the term “plan view” refers to a view from a plate thickness direction of the probe 11 or from a direction in which a central axis of a pin portion 33 of the probe 11 extends. Further, the plate thickness direction of the probe 11 or the direction in which the central axis of the pin portion 33 of the probe 11 extends may not coincide with the vertical direction.

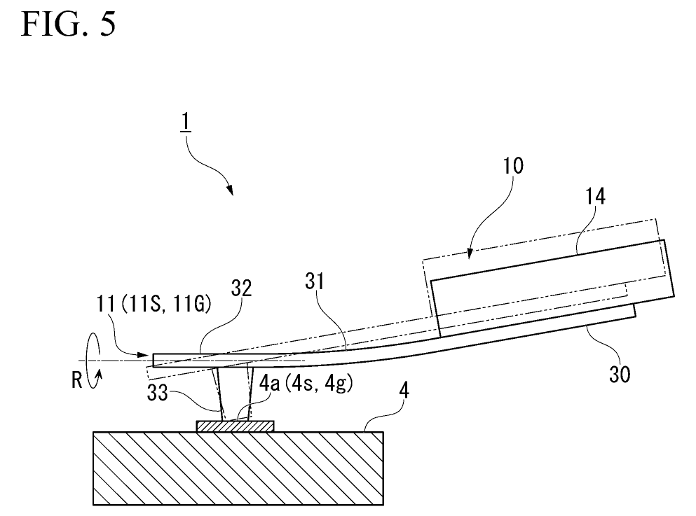

As illustrated in FIG. 4, the high-frequency probe unit 10 includes, as the probe 11, a signal probe 11S and a ground probe 11G. The signal probe 11S comes into contact with a signal electrode pad 4s of the inspection target 4 as illustrated in FIG. 5 to be described later. The ground probe 11G comes into contact with a ground electrode pad 4g of the inspection target 4.

The signal probe 11S and the ground probe 11G are provided in numbers and dispositions corresponding to a number and disposition of pads of the inspection target 4 (high-frequency device). In the present embodiment, as illustrated in FIG. 4, two signal probes 11S and two ground probes 11G are provided. The signal probe 11S transmits and receives a high-frequency signal to and from the high-frequency cable. The two signal probes 11S are each capable of transmitting and receiving a signal; for example, in one inspection target 4, one of the signal probes serves as a receiving side and the other serves as a transmitting side, while in another inspection target 4, one serves as the transmitting side and the other serves as the receiving side.

The ground probes 11G are electrically grounded and are disposed alternately with the signal probes 11S in a plan view. Of the two signal probes 11S, the ground probes 11G are disposed on both sides of one signal probe 11S (the signal probe 11S on an upper side of the paper in FIG. 4, hereinafter referred to as a first signal probe 11S). That is, the first signal probe 11S is sandwiched between the two ground probes 11G in a plan view.

Of the two signal probes 11S, the ground probe 11G is disposed on one side of the other signal probe 11S (the signal probe 11S on a lower side of the paper in FIG. 4, hereinafter referred to as a second signal probe 11S), while the dummy probe 13 is disposed on the other side of the second signal probe 11S instead of the ground probe 11G. That is, the other signal probe 11S is sandwiched between the ground probe 11G and the dummy probe 13 in a plan view. The dummy probe 13 is a ground dummy probe 13G that is electrically grounded.

If the dummy probe 13 is absent, the second signal probe 11S exhibits inferior high-frequency characteristics (for example, S11 characteristics) compared to the first signal probe 11S. The reason for this is because the first signal probe 11S is disposed in a “GSG (G: ground, S: signal)” configuration and impedance-matched, whereas the second signal probe 11S is disposed in a “GS” configuration. In the “GS” configuration, a capacitance generated between the second signal probe 11S and the ground probe 11G with respect to an inductance of the second signal probe 11S itself is halved, and both an inductance and a resistance of the ground probe 11G are doubled, thereby resulting in impedance mismatch.

If an attempt is made for the second signal probe 11S disposed in a “GS” configuration to be impedance-matched to a level equivalent to that of the first signal probe 11S disposed in a “GSG” configuration, a gap of the “GS” configuration on a transmitting side would have to be made extremely narrow or a thickness of the probe 11 would have to be made extremely thick. But this would hinder independent movement of the probe 11, hinder absorption of a step difference on a contact surface with the pad 4a of the inspection target 4 (see FIG. 5 described later), and significantly sacrifice usability of the probe 11 during overdrive (OD).

For this reason, in the present embodiment, the dummy probe 13 without the pin portion 33 is provided, a capacitance between the dummy probe 13 and the adjacent second signal probe 11S is doubled, and the ground probe 11G and the dummy probe 13 that sandwich the second signal probe 11S are short-circuited (short-circuited by a ground bridge portion 15 to be described later). Thereby, when a return current from the inspection target 4 is distributed to the ground probe 11G and the dummy probe 13 (the ground dummy probe 13G), an inductance and a resistance of the ground of the second signal probe 11S are both halved, making it possible to adjust an LCR value to the same as that of the first signal probe 11S, thereby obtaining equivalent high-frequency characteristics.

The probe 11 illustrated in FIG. 4 is a cantilever-type probe, and includes a fixed end portion 30 fixed to the main body portion 12, a pair of elastic arm portions 31 branching from the fixed end portion 30 and extending with a gap therebetween, a free end portion 32 connecting distal ends of the pair of elastic arm portions 31, and the pin portion 33 provided on the free end portion 32 and coming into contact with the inspection target 4.

The fixed end portion 30, the pair of elastic arm portions 31, and the free end portion 32 are formed in a plate-shaped body having a predetermined thickness, and such a plate-shaped body can be formed by, for example, micro electro mechanical systems (MEMS) technology. In a MEMS technology, for example, the plate-shaped body can be manufactured by laminating metal materials (conductors) such as Ni alloys on a table (not illustrated). Further, the pin portion 33 may be attached after the plate-shaped body is manufactured or may be formed simultaneously by a MEMS technology.

The fixed end portion 30 is fixed to the main body portion 12 (the probe block 20) via the pedestal portion 14. The fixed end portion 30 is formed in a substantially rectangular plate shape in a plan view. The pair of elastic arm portions 31 extend substantially parallel to each other with a gap therebetween from the fixed end portion 30. Each of the elastic arm portions 31 are formed in a plate shape having a constant width, and the pair of the elastic arm portions 31 are gradually approach each other toward the distal ends (the free end portion 32). The pair of elastic arm portions 31 are laterally symmetrical with respect to a central axis of the probe 11 in a plan view of the probe 11, like hypotenuses of an isosceles triangle or legs of an isosceles trapezoid. Further, in order to adjust an attachment position with respect to the pedestal portion 14, the fixed end portion 30 may be laterally asymmetric with respect to the central axis of the probe 11, and similarly, the pair of elastic arm portions 31 may also be laterally asymmetric on the fixed end portion 30 side with respect to the central axis of the probe 11.

An elongated hole-shaped gap is formed between the pair of elastic arm portions 31. Arc-shaped arcuate portions are formed at both end parts of the gap (elongated hole) in a longitudinal direction. A width of the gap, excluding the arcuate portions, gradually decreases in a proportional manner toward distal ends of the pair of elastic arm portions 31. The free end portion 32 is formed in a substantially arc shape and connects distal ends of the pair of elastic arm portions 31. A columnar pin portion 33 is vertically provided at a central part on a lower surface of the free end portion 32. The pin portion 33 has a tapered shape in which a diameter decreases toward a distal end (lower end).

The ground dummy probe 13G includes the fixed end portion 30, the pair of elastic arm portions 31, and the free end portion 32 among the components of the probe 11 (the fixed end portion 30, the pair of elastic arm portions 31, the free end portion 32, and the pin portion 33), and does not include the pin portion 33. Further, the fixed end portion 30 of the ground dummy probe 13G has an isosceles trapezoidal shape in a plan view in which a width on a side of the pair of elastic arm portions 31 increases.

The free end portion 32 of the ground dummy probe 13G is electrically connected to the free end portion 32 of the ground probe 11G via the ground bridge portion 15 with the second signal probe 11S interposed therebetween. Further, the ground bridge portion 15 can be formed simultaneously with the fixed end portion 30, the pair of elastic arm portions 31, and the free end portion 32 using a MEMS technology.

The ground bridge portion 15 is formed in an arc shape in a plan view and connects the free end portions 32 of the ground probe 11G and the ground dummy probe 13G to surround the pin portion 33 of the second signal probe 11S. Also, in the present embodiment, the free end portions 32 of the two ground probes 11G that sandwich the first signal probe 11S are also electrically connected to each other via the ground bridge portion 15. That is, two ground bridge portions 15 are connected to the free end portion 32 of the ground probe 11G disposed at a center of a “GSGSG” disposition.

The signal probe 11S and the ground probe 11G each have the fixed end portion 30, the pair of elastic arm portions 31, the free end portion 32, and the pin portion 33, but sizes of the gap between the pair of elastic arm portions 31 differ therebetween. Specifically, a gap W2 between the pair of elastic arm portions 31 of the ground probe 11G disposed at a center of the “GSGSG” disposition is larger than a gap W1 between the pair of elastic arm portions 31 of the signal probe 11S. Further, since a size of the gap gradually decreases toward a distal end of the probe 11, comparison is made based on a maximum width on a base end side (the fixed end portion 30 side) of the pair of elastic arm portions 31.

Also, a gap W3 between the pair of elastic arm portions 31 of the ground probe 11G disposed at an end of the “GSGSG” disposition is larger than the gap W2 between the pair of elastic arm portions 31 of the ground probe 11G disposed at the center of the “GSGSG” disposition. Further, a gap W4 between the pair of elastic arm portions 31 of the ground dummy probe 13G is larger than the gap W3 between the pair of elastic arm portions 31 of the ground probe 11G disposed at the end of the “GSGSG” disposition. That is, there is a relationship of W1 < W2 < W3 < W4.

The probe 11 and the dummy probe 13 are more likely to be elastically deformed as the gap on a base end side of the pair of elastic arm portions 31 becomes larger, and conversely, are less likely to be elastically deformed as the gap becomes smaller. Since the signal probes 11S are individually movable, the gap between the pair of elastic arm portions 31 on the base end side is made small. On the other hand, since the ground probe 11G and the ground dummy probe 13G are integrally movable via the ground bridge portion 15, the gap of the pair of elastic arm portions 31 on the base end side is made larger to match their behavior during OD with that of the signal probe 11S.

Also, among the ground probes 11G and the ground dummy probe 13G, the ground probe 11G disposed at the center of the “GSGSG” disposition has two ground bridge portions 15 connected thereto, and therefore has the gap W2. Also, the ground probe 11G disposed at an end of the “GSGSG” disposition has one ground bridge portion 15 connected thereto, and therefore has the gap W3 that is larger than the gap W2. Also, the ground dummy probe 13G is disposed at an end of the “GSGSG” disposition and does not include the pin portion 33, and therefore has the gap W4 that is larger than the gap W3. That is, the gap W4 of the ground dummy probe 13G is the largest.

FIG. 5 is an explanatory view illustrating a state in which the probe 11 is elastically deformed during OD of the high-frequency probe unit 10 according to the first embodiment.

As illustrated in FIG. 5, during OD, a distal end (needle tip) of the pin portion 33 of the probe 11 is pressed against the pad 4a of the inspection target 4. At this time, the probe 11 receives a reaction force from the pad 4a, but since the free end portion 32 supporting the pin portion 33 is stably supported by the pair of elastic arm portions 31, rotation of the probe 11 in a roll direction R around the central axis is suppressed. Therefore, the probe 11 can be stably brought into contact with the inspection target 4, and electrical characteristics of the inspection target 4 can be appropriately inspected via a high-frequency signal. Also, in the present embodiment, as illustrated in FIG. 4, since sizes of the gaps between the pair of elastic arm portions 31 of the probe 11 and the dummy probe 13 are adjusted, their behavior during OD becomes similar, and it is possible to control needle pressures of the respective pin portions 33 to be the same while providing the ground bridge portion 15.

As described above, the high-frequency probe unit 10 according to the present embodiment includes the probe 11 that comes into contact with the inspection target 4, and the main body portion 12 that supports the probe 11 and to which a high-frequency cable for transmitting and receiving a high-frequency signal to and from the inspection target 4 via the probe 11 is attachable, in which the probe 11 includes the fixed end portion 30 fixed to the main body portion 12, the pair of elastic arm portions 31 branching from the fixed end portion 30 and extending with a gap therebetween, the free end portion 32 connecting distal ends of the pair of elastic arm portions 31, and the pin portion 33 provided on the free end portion 32 and coming into contact with the inspection target 4. According to this configuration, the probe 11 can be stably brought into contact with the inspection target 4, and electrical characteristics of the inspection target 4 can be appropriately inspected via a high-frequency signal.

Also, in the present embodiment, the probe 11 includes the signal probe 11S coming into contact with the signal electrode pad 4s of the inspection target 4 and the ground probe 11G coming into contact with the ground electrode pad 4g of the inspection target 4. According to this configuration, an inductance and a resistance can be adjusted by a disposition of the ground probe 11G with respect to the signal probe 11S, thereby improving high-frequency characteristics of the high-frequency probe unit 10.

Also, in the present embodiment, the high-frequency probe unit 10 includes, among the components of the probe 11, the ground dummy probe 13G that does not have the pin portion 33, in which the signal probe 11S is disposed between the ground probe 11G and the ground dummy probe 13G in a plan view. According to this configuration, the second signal probe 11S disposed in the “GS” configuration can be impedance-matched to a level equivalent to that of the first signal probe 11S disposed in the “GSG” configuration.

Also, in the present embodiment, the high-frequency probe unit 10 includes the ground bridge portion 15 electrically connecting the ground probe 11G and the ground dummy probe 13G. According to this configuration, the ground probe 11G and the ground dummy probe 13G are connected to each other, and impedance characteristics of the signal probe 11S can be adjusted.

Also, in the present embodiment, the gap between the pair of elastic arm portions 31 of the ground dummy probe 13G is larger than the gap between the pair of elastic arm portions 31 of the ground probe 11G. According to this configuration, the ground dummy probe 13G that does not have the pin portion 33 is made more easily elastically deformable, thereby making it possible not to hinder elastic deformation of the ground probe 11G connected via the ground bridge portion 15.

In the present embodiment, the ground bridge portion 15 connects the free end portion 32 of the ground probe 11G and the free end portion 32 of the ground dummy probe 13G to surround the pin portion 33 of the signal probe 11S in a plan view. According to this configuration, impedance characteristics can be adjusted up to a distal end of the signal probe 11S including the pin portion 33.

Also, the inspection device 1 according to the present embodiment is connected to the main body portion 12 of the high-frequency probe unit 10 via a high-frequency cable, and inspects electrical characteristics of the inspection target 4. According to this configuration, an inspection accuracy of the inspection target 4 (high-frequency device) can be improved.

### Second embodiment

Next, a second embodiment of the present invention will be described. In the following description, components that are the same as or equivalent to those of the above-described embodiment are denoted by the same reference signs, and description thereof will be simplified or omitted.

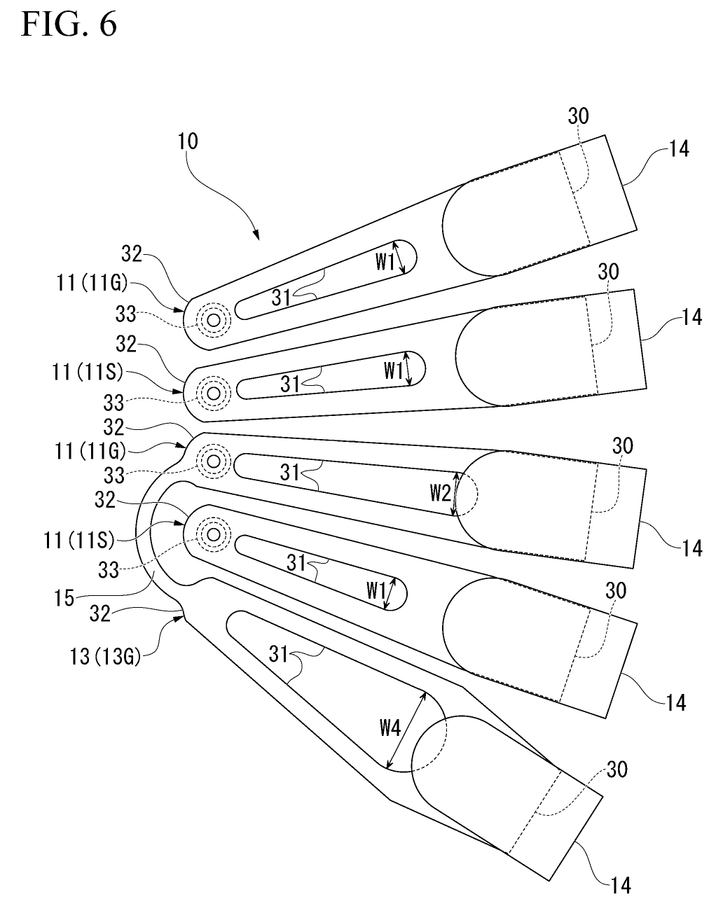

FIG. 6 is a plan view of a probe 11 and a dummy probe 13 according to the second embodiment. In the second embodiment, as illustrated in FIG. 6, the probe 11 and the dummy probe 13 are disposed in an order of “GSGSG”. Also, in the second embodiment, only one ground bridge portion 15 is provided to connect a free end portion 32 of a ground probe 11G disposed at a center of the “GSGSG” disposition and the free end portion 32 of a ground dummy probe 13G disposed at an end of the “GSGSG” disposition.

In the second embodiment, a gap W2 between a pair of elastic arm portions 31 of the ground probe 11G disposed at a center of the “GSGSG” disposition is larger than a gap W1 between the pair of elastic arm portions 31 of a signal probe 11S and the ground probe 11G that are not connected by the ground bridge portion 15. Also, a gap W4 between the pair of elastic arm portions 31 of the ground dummy probe 13G is larger than the gap W2 between the pair of elastic arm portions 31 of the ground probe 11G disposed at a center of the “GSGSG” disposition. Thereby, similarly to the first embodiment, behavior during overdrive (OD) of the ground probe 11G and the ground dummy probe 13G connected by the ground bridge portion 15 can be matched with behavior during OD of the signal probe 11S and the ground probe 11G that are not connected by the ground bridge portion 15.

### Third embodiment

Next, a third embodiment of the present invention will be described. In the following description, components that are the same as or equivalent to those of the above-described embodiments are denoted by the same reference signs, and description thereof will be simplified or omitted.

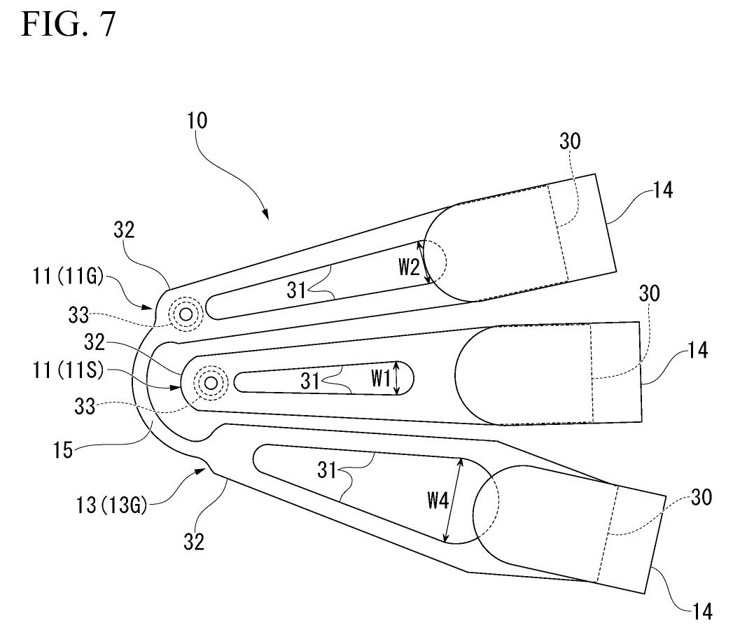

FIG. 7 is a plan view of a probe 11 and a dummy probe 13 according to the third embodiment. In the third embodiment, as illustrated in FIG. 7, the probe 11 and the dummy probe 13 are disposed in an order of “GSG”. A ground bridge portion 15 connects a free end portion 32 of a ground probe 11G disposed at one end of the “GSG disposition and the free end portion 32 of a ground dummy probe 13G disposed at the other end of the “GSG” disposition.

Specifically, in the third embodiment, the ground probe 11G, a signal probe 11S, and the ground dummy probe 13G are disposed in that order from an upper side of the paper to a lower side of the paper in FIG. 7. In the third embodiment, since only one signal probe 11S is provided and is individually movable, a size of a gap between a pair of elastic arm portions 31 is W1. A gap W2 between the pair of elastic arm portions 31 of the ground probe 11G is larger than the gap W1 between the pair of elastic arm portions 31 of the signal probe 11S. Also, a gap W4 between the pair of elastic arm portions 31 of the ground dummy probe 13G is larger than the gap W2 between the pair of elastic arm portions 31 of the ground probe 11G. Thereby, similarly to the first embodiment, behavior during overload (OD) of the ground probe 11G and the ground dummy probe 13G connected by the ground bridge portion 15 can be matched with behavior during OD of the signal probe 11S that is not connected by the ground bridge portion 15. Also, similarly to the above-described embodiments, impedance characteristics can be adjusted up to a distal end of the signal probe 11S.

### Fourth embodiment

Next, a fourth embodiment of the present invention will be described. In the following description, components that are the same as or equivalent to those of the above-described embodiments are denoted by the same reference signs, and description thereof will be simplified or omitted.

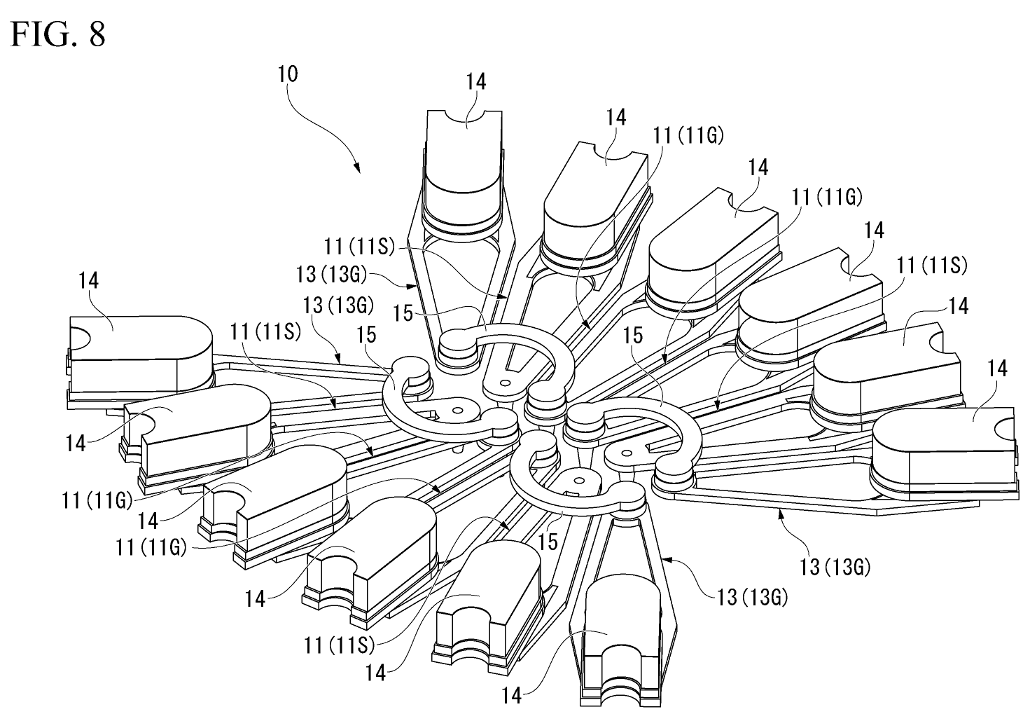

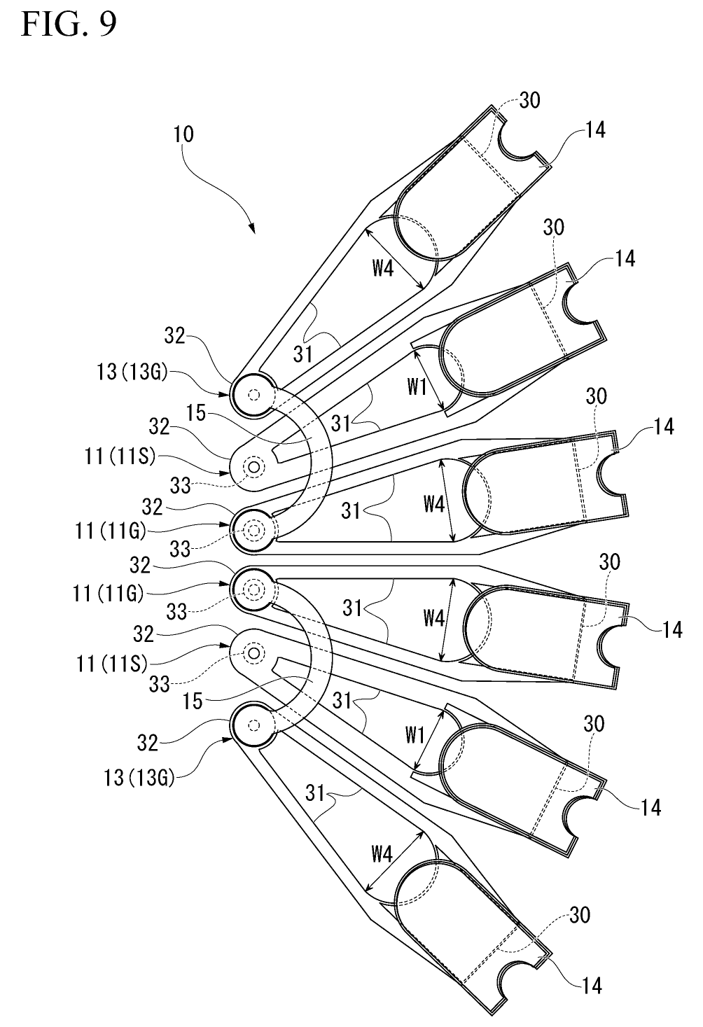

FIG. 8 is a perspective view of a probe 11 and a dummy probe 13 according to the fourth embodiment. FIG. 9 is a plan view of the probe 11 and the dummy probe 13 according to the fourth embodiment.

In the fourth embodiment, as illustrated in FIGS. 8 and 9, the probe 11 and the dummy probe 13 are disposed in an order of “GSGGSG”. Also, in the fourth embodiment, a ground bridge portion 15 connects free end portions 32 of a ground probe 11G and a ground dummy probe 13G to each other to surround a pin portion 33 of a signal probe 11S and to straddle the signal probe 11S in a plan view.

Specifically, in the fourth embodiment, the ground dummy probe 13G, the first signal probe 11S, the ground probe 11G, the ground probe 11G, the second signal probe 11S, and the ground dummy probe 13G are disposed in that order from an upper side of the paper to a lower side of the paper in FIG. 9. The two signal probes 11S of the fourth embodiment are individually movable, and therefore have a common gap size W1 between the pair of elastic arm portions 31. The ground probe 11G and the ground dummy probe 13G are movable integrally for each set connected by the ground bridge portion 15, and therefore have a common gap size W4 between the pair of elastic arm portions 31. Even with this configuration, similarly to the above-described embodiments, the second signal probe 11S can be impedance-matched to a level equivalent to that of the first signal probe 11S, while behavior during overdrive (OD) of the two signal probes 11S and the two ground probes 11G can be matched.

Also, in the fourth embodiment, the ground bridge portion 15 connects the free end portion 32 of the ground probe 11G and the free end portions 32 of the ground dummy probe 13G to surround the pin portion 33 of the signal probe 11S and straddle the signal probe 11S in a plan view. According to this configuration, since the ground probe 11G and the ground dummy probe 13G are connected to adjust impedance characteristics of the signal probe 11S, and the ground bridge portion 15 does not protrude toward a distal end side (the free end portion 32 side) of the probe 11 compared to the configurations illustrated in FIGS. 4, 6, and 7, the high-frequency probe unit 10 can be made smaller in size. Further, in the fourth embodiment, the ground bridge portion 15 may be formed simultaneously with other components of the probe 11 by a MEMS technology, or may be attached as a separate component. Also, in the configuration illustrated in FIG. 9, the ground bridge portion 15 is convexly curved toward a base end side (the fixed end portion 30 side) of the probe 11, but as in the configurations illustrated in FIGS. 4, 6 and 7, the ground bridge portion 15 may also be convexly curved toward the distal end side (the free end portion 32 side) of the probe 11.

### Fifth embodiment

Next, a fifth embodiment of the present invention will be described. In the following description, components that are the same as or equivalent to those of the above-described embodiments are denoted by the same reference signs, and description thereof will be simplified or omitted.

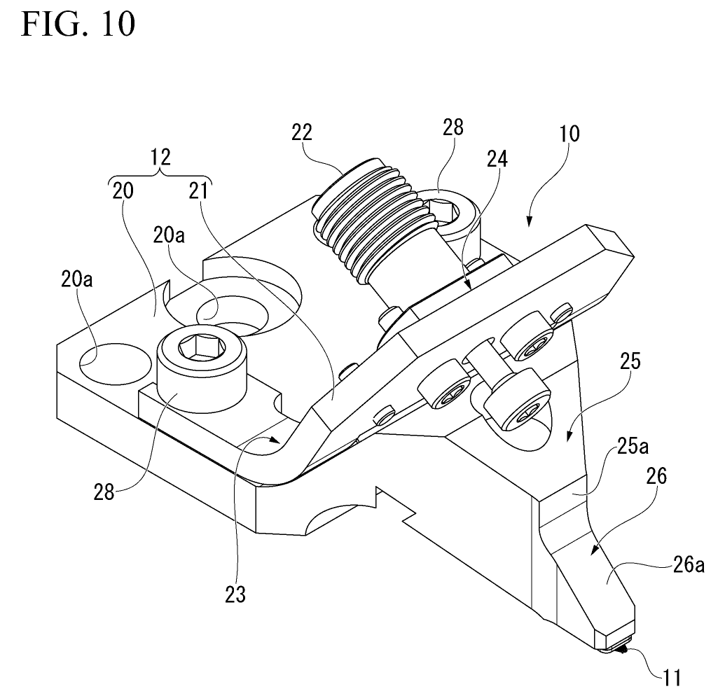

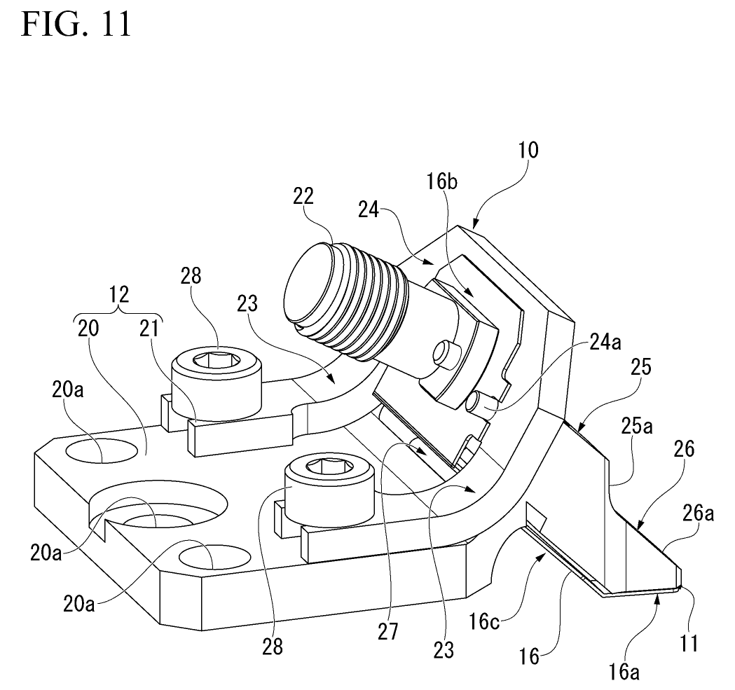

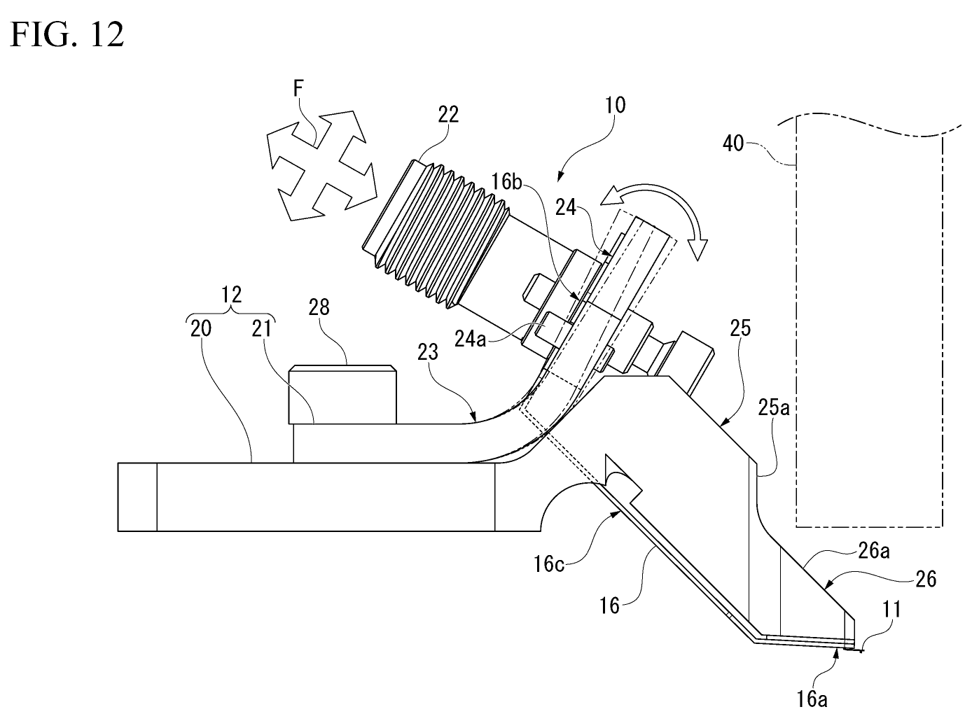

FIG. 10 is a perspective view of a high-frequency probe unit 10 according to the fifth embodiment from a front upper side. FIG. 11 is a perspective view of the high-frequency probe unit 10 according to the fifth embodiment from a rear upper side. FIG. 12 is a side view of the high-frequency probe unit 10 according to the fifth embodiment.

As illustrated in FIG. 10, the high-frequency probe unit 10 includes a probe 11 and a main body portion 12 that supports the probe 11.

The main body portion 12 includes a probe block 20 that supports the probe 11, and a connector holder 21 that has a connector 22 to which a high-frequency cable can be attached. The high-frequency probe unit 10 of the fifth embodiment is a single type having one connector 22, but may be a dual type having two connectors 22 as illustrated in FIG. 2 described above.

The probe block 20 and the connector holder 21 are made of a metal material such as, for example, iron or aluminum. Further, the connector holder 21 may be formed of a material or composition different from that of the probe block 20 as long as the connector holder 21 is more easily elastically deformable than the probe block 20, and may also be formed of the same material or composition provided that the connector holder 21 is shaped to be more easily elastically deformable. When a portion of the probe block 20 that supports the probe 11 is defined as the front, the connector holder 21 is fixed to the rear of the probe block 20 via a bolt 28 (fixing member).

The probe block 20 includes a first portion 25 that protrudes forward of the connector holder 21 and has a vertical surface 25a formed at a front end thereof, and a second portion 26 that protrudes forward from the first portion 25 and has an inclined surface 26a formed to be connected a lower end of the vertical surface 25a and extending obliquely downward. Further, as illustrated in FIG. 11, a through hole 27 through which a flexible printed circuit board 16 passes to a lower surface side of the probe block 20 is formed in the first portion 25.

As illustrated in FIG. 12, the probe 11 is attached to a lower surface of the second portion 26 and is supported to protrude forward from a front end of the second portion 26. A microscope 40 for observing the probe 11 can be disposed above the probe 11. When the vertical surface 25a is provided on the first portion 25 and the inclined surface 26a is provided on the second portion 26, the microscope 40 can be disposed close to the probe 11 while avoiding interference between the probe block 20 and the microscope 40.

The connector holder 21 is configured to be elastically deformable independently of the probe block 20 that supports the probe 11. Specifically, as illustrated in FIG. 11, the connector holder 21 includes a pair of leg portions 23 and a support portion 24 that is provided to span between the pair of leg portions 23 and supports the connector 22. The pair of leg portions 23 are bent in a substantially L shape in a side view. Rear end parts of the pair of leg portions 23 are each fixed to a front side of an attachment hole 20a of the probe block 20 via the bolt 28.

The pair of leg portions 23 extend forward along an upper surface of the probe block 20 from the rear end parts fixed to the probe block 20 and then are bent or curved upward at an angle of approximately 60° to separate from the upper surface of the probe block 20. The support portion 24 is formed in a flat plate shape and connects upper end parts of the pair of leg portions 23 to each other. A positioning protrusion portion 24a for positioning the flexible printed circuit board 16 is provided upright on the support portion 24.

The flexible printed circuit board 16 electrically connects the probe 11 and the connector 22. The flexible printed circuit board 16 has a first fixed end 16a connected to the probe 11, a second fixed end 16b connected to the connector 22, and a flexing portion 16c provided between the first fixed end 16a and the second fixed end 16b and capable of following elastic deformation of the connector holder 21. The flexing portion 16c is not fixed and is suspended in a free state.

The first fixed end 16a is fixed to a lower surface of the second portion 26 of the probe block 20. The second fixed end 16b is positioned by the positioning protrusion portion 24a on the support portion 24 of the connector holder 21, and is fixed in a state of being sandwiched between the connector 22 and the support portion 24. The flexing portion 16c passes through the through hole 27 and is suspended below the first portion 25 and the second portion 26 with a gap therebetween.

Incidentally, when high-frequency measurement is performed using the high-frequency probe unit 10, a high-frequency cable is connected from an inspection device 1 to the connector 22. A relatively thick high-frequency cable is normally employed from viewpoints of high-frequency characteristics, reproducibility, and low DC resistance. If the high-frequency cable is bent due to a positional relationship between the inspection device 1 and the high-frequency probe unit 10, a load F caused by an own weight of the high-frequency cable or bending of the high-frequency cable is applied to the connector 22 as illustrated in FIG. 12.

Such a load F can be absorbed by the connector holder 21 performing a spring action (elastic deformation) independently of the probe block 20 as illustrated in FIG. 12. Therefore, the load F caused by the own weight or bending of the high-frequency cable can be prevented from being transmitted to the probe block 20 and the probe 11. Thereby, it is possible to avoid a problem of deterioration in positioning accuracy of a needle tip of the probe 11.

As described above, in the fifth embodiment, the main body portion 12 includes the probe block 20 that supports the probe 11 and the connector holder 21 that supports the connector 22 to which a high-frequency cable is attachable, in which the connector holder 21 is elastically deformable independently of the probe block 20. According to this configuration, the connector holder 21 can absorb the load F that is applied to the connector 22 due to the own weight or bending of the high-frequency cable, and therefore a positioning accuracy of the needle tip of the probe 11 can be improved.

Also, the connector holder 21 includes the pair of leg portions 23 that are attached to the rear of the probe block 20, when a portion of the probe block 20 supporting the probe 11 is defined as the front, and are bent in a side view, and the support portion 24 provided to span between the pair of leg portions 23 and supporting the connector 22. According to this configuration, since portions from bent portions of the pair of leg portions 23 to the support portion 24 can be positively elastically deformed, it is possible to make it difficult for the load F to be transmitted to the rear end parts of the pair of leg portions 23 fixed to the probe block 20.

Also, the probe block 20 includes the first portion 25 protruding forward of the connector holder 21 and having the vertical surface 25a formed at the front end thereof, and the second portion 26 protruding forward from the first portion 25 and having the inclined surface 26a that is formed to be connected to the lower end of the vertical surface 25a and extends obliquely downward, in which the probe 11 is supported to protrude forward from the front end of the second portion 26. According to this configuration, when the microscope 40 is disposed in close proximity above the probe 11 as illustrated in FIG. 12, interference between the probe block 20 and the microscope 40 can be avoided.

Also, the high-frequency probe unit 10 includes the flexible printed circuit board 16 electrically connecting the probe 11 and the connector 22, in which the flexible printed circuit board 16 has the first fixed end 16a connected to the probe 11, the second fixed end 16b connected to the connector 22, and the flexing portion 16c provided between the first fixed end 16a and the second fixed end 16b and configured to follow elastic deformation of the connector holder 21. According to this configuration, even when the connector holder 21 performs a spring action, since the flexible printed circuit board 16 can follow the movement of the spring action, disconnection or the like between the probe 11 and the connector 22 can be prevented.

While preferred embodiments of the present invention have been described and illustrated, it should be understood that these are exemplary of the present invention and are not to be considered as limiting. Additions, omissions, substitutions, and other modifications can be made without departing from the scope of the present invention. Accordingly, the present invention is not to be considered as being limited by the foregoing description and is only limited by the scope of the claims.

For example, in the embodiments described above, a case in which the high-frequency probe unit 10 includes two connectors 22 has been exemplified, but the present invention is also applicable to a case in which one connector 22 or three or more connectors 22 are provided in accordance with the number of signal probes 11S. Also, the number and disposition of the probes 11 and the dummy probes 13 of the high-frequency probe unit 10 are not limited to those in the above-described embodiments.

In addition, the components in the above-described embodiments can be appropriately replaced with well-known components within a range not departing from the spirit of the present invention, and the above-described embodiments and modified examples may be appropriately combined.

For example, some or all of the above-described embodiments can be added as supplementary notes as follows. Further, the configurations described in the following supplementary notes are not limited to the probes having a gap as illustrated in FIGS. 4 and 6-9, and are also applicable to probes having no gaps and needle-shaped probes.

### Supplementary note 1-1

A high-frequency probe unit including:
a probe that comes into contact with an inspection target; and
a main body portion that supports the probe and to which a high-frequency cable for transmitting and receiving a high-frequency signal to and from the inspection target via the probe is attachable, in which
the main body portion includes:
a probe block supporting the probe; and
a connector holder supporting a connector to which the high-frequency cable is attachable, in which
the connector holder is elastically deformable independently of the probe block.

### Supplementary note 1-2

The high-frequency probe unit according to Supplementary note 1-1, wherein the connector holder includes:
a pair of leg portions which are attached to the rear of the probe block when a portion of the probe block supporting the probe is defined as the front, and are bent in a side view; and
a support portion provided to span between the pair of leg portions and supporting the connector.

### Supplementary note 1-3

The high-frequency probe unit according to Supplementary note 1-1 or 1-2, wherein the probe block includes:
a first portion protruding forward of the connector holder and having a vertical surface formed at a front end thereof; and
a second portion protruding forward from the first portion and having an inclined surface that is formed to be connected to a lower end of the vertical surface and extends obliquely downward, in which
the probe is supported to protrude forward from a front end of the second portion.

### Supplementary note 1-4

The high-frequency probe unit according to any one of Supplementary notes 1-1 to 1-3, further including a flexible printed circuit board electrically connecting the probe and the connector, wherein the flexible printed circuit board has:
a first fixed end connected to the probe;
a second fixed end connected to the connector; and
a flexing portion provided between the first fixed end and the second fixed end and configured to follow elastic deformation of the connector holder.

### Supplementary note 1-5

An inspection device connected to the main body portion of the high-frequency probe unit according to any one of Supplementary notes 1-1 to 1-4 via the high-frequency cable, and configured to inspect electrical characteristics of the inspection target.

What is claimed is:

1. A high-frequency probe unit comprising:
a probe which comes into contact with an inspection target; and
a main body portion which supports the probe and to which a high-frequency cable for transmitting and receiving a high-frequency signal to and from the inspection target via the probe is attachable, wherein
the probe includes:
a fixed end portion fixed to the main body portion;
a pair of elastic arm portions branching from the fixed end portion and extending with a gap therebetween;
a free end portion connecting distal ends of the pair of elastic arm portions; and
a pin portion provided on the free end portion and coming into contact with the inspection target.

2. The high-frequency probe unit according to claim 1, wherein the probe includes:
a signal probe coming into contact with a signal electrode pad of the inspection target; and
a ground probe coming into contact with a ground electrode pad of the inspection target.

3. The high-frequency probe unit according to claim 2, further comprising, among the components of the probe, a ground dummy probe which does not have the pin portion, wherein
the signal probe is disposed between the ground probe and the ground dummy probe in a plan view.

4. The high-frequency probe unit according to claim 3, further comprising a ground bridge portion electrically connecting the ground probe and the ground dummy probe.

5. The high-frequency probe unit according to claim 4, wherein a gap between the pair of elastic arm portions of the ground dummy probe is larger than a gap between the pair of elastic arm portions of the ground probe.

6. The high-frequency probe unit according to claim 4, wherein the ground bridge portion connects the free end portion of the ground probe and the free end portion of the ground dummy probe to surround the pin portion of the signal probe in a plan view.

7. The high-frequency probe unit according to claim 4, wherein the ground bridge portion connects the free end portion of the ground probe and the free end portion of the ground dummy probe to surround the pin portion of the signal probe and straddle the signal probe in a plan view.

8. The high-frequency probe unit according to claim 1, wherein the main body portion includes:
a probe block supporting the probe; and
a connector holder supporting a connector to which the high-frequency cable is attachable, wherein
the connector holder is elastically deformable independently of the probe block.

9. The high-frequency probe unit according to claim 8, wherein the connector holder includes:
a pair of leg portions which are attached to the rear of the probe block when a portion of the probe block supporting the probe is defined as the front, and are bent in a side view; and
a support portion provided to span between the pair of leg portions and supporting the connector.

10. The high-frequency probe unit according to claim 8, wherein the probe block includes:
a first portion protruding forward of the connector holder and having a vertical surface formed at a front end thereof; and
a second portion protruding forward from the first portion and having an inclined surface which is formed to be connected to a lower end of the vertical surface and extends obliquely downward, in which
the probe is supported to protrude forward from a front end of the second portion.

11. The high-frequency probe unit according to claim 8, further comprising a flexible printed circuit board electrically connecting the probe and the connector, wherein the flexible printed circuit board has:
a first fixed end connected to the probe;
a second fixed end connected to the connector; and
a flexing portion provided between the first fixed end and the second fixed end and configured to follow elastic deformation of the connector holder.

12. An inspection device connected to the main body portion of the high-frequency probe unit according to claim 1 via the high-frequency cable, and configured to inspect electrical characteristics of the inspection target.
